(19) United States
(12) Patent Application Publication
(10) Pub. No.: US 2009/0140813 A1
(43) Pub. Date: Jun. 4, 2009

(54) RECEIVED SIGNAL GAIN CONTROL METHOD AND RADIO FREQUENCY SIGNAL RECEIVING APPARATUS

(75) Inventors: Byung Su KANG, Daejeon (KR); Heon Kook KWON, Daejeon (KR); Kwang Chun LEE, Daejeon (KR)

Correspondence Address: CANTOR COLBURN, LLP, 20 Church Street, 22nd Floor, Hartford, CT, 06103, US

(73) Assignee: Electronics and Telecommunications Research Institute, Daejeon (KR)

(21) Appl. No.: 12/234,115

(22) Filed: Sep. 19, 2008

(30) Foreign Application Priority Data
Nov. 29, 2007 (KR) 10-2007-0122749

(51) Int. Cl. H03G 3/20

(52) U.S. Cl. 330/278

(57) ABSTRACT

A radio signal receiving apparatus receiving a radio signal over a radio channel generates a first amplified signal by amplifying the radio signal with a first gain, and determines the first gain by measuring the strength of the first amplified signal. In addition, the radio signal receiving apparatus generates a down-converted signal by frequency down-converting the first amplified signal, and generates a second amplified signal by amplifying the down-converted signal with a second gain. In addition, the radio signal receiving apparatus determines the second gain by measuring the strength of the second amplified signal.

### CROSS-REFERENCE TO RELATED APPLICATION

This application claims priority to and the benefit of Korean Patent Application No. 10-2007-0122749 filed in the Korean Intellectual Property Office on Nov. 29, 2007, the entire contents of which are incorporated herein by reference.

### BACKGROUND OF THE INVENTION

(a) Field of the Invention

The present invention relates to a received signal gain control method and a radio signal receiving apparatus.

This work was supported by the IT R&S program of MIC/IITA [2005-S-404-13, Research & Development of Radio Transmission Technology for 3G evolution].

(b) Description of the Related Art

A typical receiving apparatus of a wireless communication system performs gain control by amplifying a received radio signal with a predetermined gain.

The receiving apparatus frequency down-converts the received radio signal and converts the frequency down-converted radio signal to a digital signal, and measures the strength of the signal in the digital signal state with a predetermined interval. In addition, the receiving apparatus generates a gain according to the measured strength, and generates a digital voltage control signal for gain control according to the generated gain.

Further, the receiving apparatus includes an amplifier that performs low-noise amplification on a radio signal before the frequency down-conversion, and an amplifier that performs auto gain control amplification on a baseband signal after the frequency down-conversion.

Accordingly, the typical receiving apparatus must include additional access for applying the digital voltage control signal, which has been generated in accordance with a gain, to the amplifier that performs the low-noise amplification. As described, conversion from a digital voltage control signal to an analog voltage control signal causes occurrence of unexpected noise.

Further, since the typical receiving apparatus generates a gain by measuring the strength of a radio signal with a predetermined interval, operation for comparing the measured strength and a reference value is persistently performed even though a strength variation rate of the received signal is low. Such a persistent operation increases power consumption of the receiving apparatus.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a radio signal receiving apparatus that can reduce noise and power consumption, and a received signal gain control method thereof.

An exemplary radio signal amplifying method according to an embodiment of the present invention includes: generating a first amplified signal by amplifying the radio signal with a first gain; determining the first gain by measuring the strength of the first amplified signal; frequency down-converting the first amplified signal for generating the down-converted signal; generating a second amplified signal by amplifying the down-converted signal with a second gain; and determining the second gain by measuring the strength of the second amplified signal.

The generation of the first amplified signal includes amplifying the radio signal through a plurality of amplifiers, and the determination of the first gain includes determining turn-on/turn-off of each of the respective amplifiers according to the first gain. The determination of the first gain further includes measuring the strength of the first amplified signal in the state of an analog signal.

The determining of the second gain includes: measuring a strength difference value between the strength of the second amplified signal and the strength of a second amplified signal at the previous time; generating the second gain according to the strength difference value when the strength difference value is greater than a reference value; and maintaining the second gain at a level of the second gain of the previous time when the strength difference value is smaller than the reference value. Herein, the generation of the second gain further includes setting a time interval for measuring the strength of the second amplified signal with an initial value, and the maintaining the second gain at the level of the second gain of the previous time further includes setting a time interval for measuring the strength of the second amplified signal to be longer than the present time interval. The determination of the second gain further includes measuring the strength of the second amplified in the state of a digital signal.

An exemplary radio signal receiving apparatus according to an embodiment of the present invention includes an amplifier, a first strength measurer, a first power controller, a mixer, an amplifier, a second measurer, and a second power controller. The amplifying end generates a first amplified signal by amplifying the radio signal with a first gain. The first strength measurer measures the strength of the first amplified signal. The mixer generates a down-converted signal by frequency down-converting the first amplified signal. The amplifier generates a second amplified signal by amplifying the down-converted signal with a second gain. The second measurer measures the strength of the second amplified signal. The second power controller determines the second gain according to the strength of the second amplified signal.

The amplifying end includes a plurality of amplifiers that respectively amplify an input signal with each gain and output an amplified signal, and a plurality of switches that respectively determine turn-on/turn-off of each of the plurality of amplifiers.

The first power controller applies an on-off control signal to the plurality of switches that are respectively connected with the plurality of amplifiers according to the first gain.

The first strength measurer measures the strength of the first amplified signal in the state of an analog signal.

The radio signal receiving apparatus further includes a converter that converts the second amplified signal from an analog format to a digital format. The second strength measurer measures the second amplified signal in the state of a digital signal.

The second power controller generates the second gain when a strength difference value between the second amplified signal and a second amplified signal of the previous time is greater than a reference value. The second power controller sets a time interval for the second strength measurer to measure the strength of the second amplified signal with an initial value when the strength difference value is greater than the reference value.

The second power controller maintains the second gain at a level of a second gain of the previous time when a strength difference value between the second amplified signal and a second amplified signal of the previous time is smaller than a reference value. The second power controller sets a time interval for the second strength measurer to measure the strength of the second amplified signal to be longer than a time interval of the present time when the strength difference value is smaller than the reference value.

The radio signal receiving apparatus further includes a control signal generator for generating a control signal that changes a gain resistance of the amplifier according to the second gain.

According to the present invention, low-noise amplification is gradually performed with a gain according to a strength of a received signal measured in the state of an RF signal and AGC amplification is performed with a gain according to the strength of the received signal measured in the state of a digital signal so that a variation range of the AGC amplification and noise can be reduced. In addition, a time interval for measuring the strength of the radio signal in the state of a digital signal can be variably set according to a variation rate of the strength measured in the state of a digital signal, and accordingly, unnecessary operation and control signal generation can be reduced, thereby reducing power consumption.

### BRIEF DESCRIPTION OF THE DRAWINGS

FIG. 1 is a block diagram of a radio signal receiving apparatus according to an exemplary embodiment of the present invention.

FIG. 2 is a flowchart of a radio signal receiving method according to an exemplary embodiment of the present invention.

FIG. 3 is a block diagram of a radio frequency (RF) signal processor of FIG. 1 according to the exemplary embodiment of the present invention.

FIG. 4 is a block diagram of a baseband signal processor of FIG. 1 according to the exemplary embodiment of the present invention.

FIG. 5 is a flowchart of a secondary gain calculating method according to the exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

In addition, unless explicitly described to the contrary, the word “comprise” and variations such as “comprises” or “comprising” will be understood to imply the inclusion of stated elements but not the exclusion of any other elements. In addition, the terms “-er”, “-or”, and “module” described in the specification mean units for processing at least one function and operation and can be implemented by hardware components or software components and combinations thereof.

Throughout the specification, a mobile station (MS) represents a terminal, a mobile terminal (MT), a subscriber station (SS), a portable subscriber station (PSS), user equipment (UE), and an access terminal (AT), and includes entire or partial functions of the mobile terminal, subscriber station, portable subscriber station, and user equipment.

A base station (BS) represents an access point (AP), a radio access station (RAS), a node B (Node-B), a base transceiver station (BTS), and a mobile multihop relay (MMR)-BS, and includes entire or partial functions of the AP, RAS, Node-B, BTS, and MMR-BS.

A received signal gain control method and a radio signal receiving apparatus according to an exemplary embodiment of the present invention will be described in further detail with reference to the drawings.

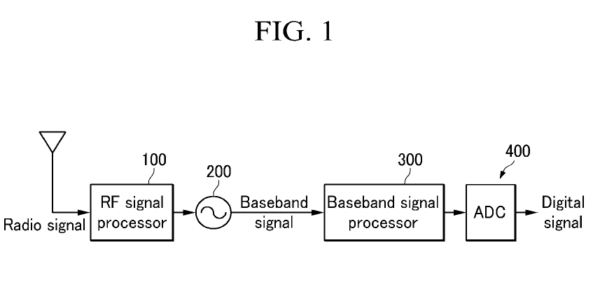

FIG. 1 shows a block diagram of a radio signal receiving apparatus according to an exemplary embodiment of the present invention.

As shown in FIG. 1, the radio signal receiving apparatus according to the exemplary embodiment of the present invention includes a radio frequency (RF) signal processor 100, a mixer 200, a baseband signal processor 300, and an analog-to-digital converter (ADC) 400.

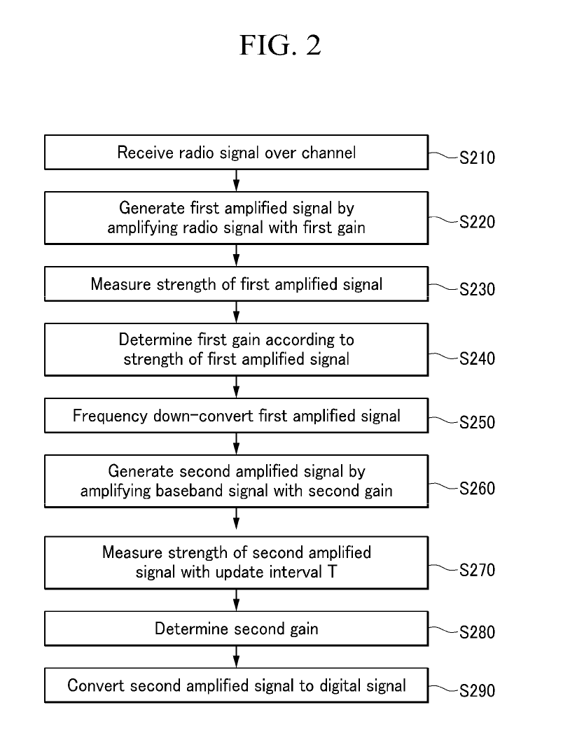

FIG. 2 shows a flowchart of a radio signal receiving method according to the exemplary embodiment of the present invention.

The radio signal receiving apparatus receives a radio signal over a channel by using an antenna (S210). Herein, the channel may be a downlink channel or an uplink channel.

The antenna applies the received radio signal to the RF signal processor 100.

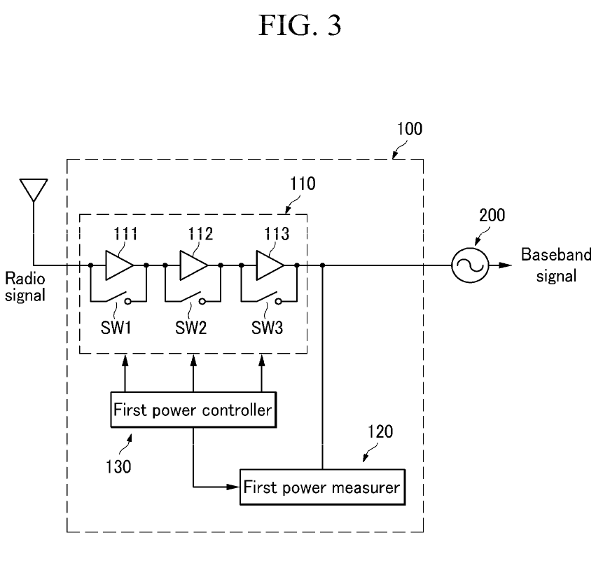

FIG. 3 shows a block diagram of the RF signal processor of FIG. 1 according to the exemplary embodiment of the present invention.

As shown in FIG. 3, the RF signal processor 100 includes a low noise amplifier 110, a first power measurer 120, and a first power controller 130. The low noise amplifier 110 includes a plurality of amplifiers 111, 112, and 113, each of which amplifies an input signal with each gain, and a plurality of switches SW1, SW2, and SW3, each of which selectively turns on/off each of the respective amplifiers.

The low noise amplifier 110 gradually amplifies the received signal with a first gain by activating/deactivating each of the plurality of amplifiers 111, 112, and 113 so as to generate a first amplified signal (S220). In this instance, the low noise amplifier 110 gradually controls gain control with respect to a radio frequency (RF) signal, and the “gradual control” of the low noise amplifier 110 is determined by the amplifier order which has the same meaning of the number of plurality of amplifiers. The number of amplifies included in the low noise amplifier 110 and a gain of each of the amplifiers 111, 112, and 113 can be determined by a wireless communication channel environment and service requirement of a wireless communication system that uses the radio signal receiving apparatus.

In addition, the low noise amplifier 110 activates/deactivates the respective amplifiers 111, 112, and 113 by turning on/off the respective switches SW1, SW2, and SW3. The turn-on/turn-off of the plurality of switches SW1, SW2, and SW3 are determined by a control signal that is generated in accordance with the first gain by the first power controller 130. The first gain is determined by the strength of the received signal measured in the state of an RF signal, and determination of the first gain will now be described in further detail.

The first power measurer 120 measures the strength of the first amplified signal and applies the measured strength value to the first power controller 130 (S230). The first power measurer 120 may be a received signal strength indicator (RSSI) that measures the strength of a radio signal that is low noise-amplified in the state of an RF signal.

The first power controller 130 determines the strength of the first amplified signal (S240). In this instance, the first power controller 130 compares the strength of the first amplified signal and a reference strength, and determines the first gain according to the comparison result. The first power controller 130 applies a turn-on/turn-off control signal of each of the switches SW1, SW2, and SW3 to the respective switches SW1, SW2, and SW3 of the low noise amplifier 110 according to the first gain.

As described, the first gain applied to the low-noise amplifier that amplifies the radio signal in the state of the RF signal is determined by the strength of the radio signal in the state of the RF signal.

As shown in FIG. 1, the mixer 200 frequency down-converts the first amplified signal (S250). The mixer 200 may generate a baseband signal or an intermediate frequency (IF) signal by frequency down-converting the first amplified signal in the state of the RF signal. Hereinafter, it is assumed that the mixer 200 generates the baseband signal by frequency down-converting the first amplified signal.

In addition, the mixer 200 applies the baseband signal to the baseband signal processor 300.

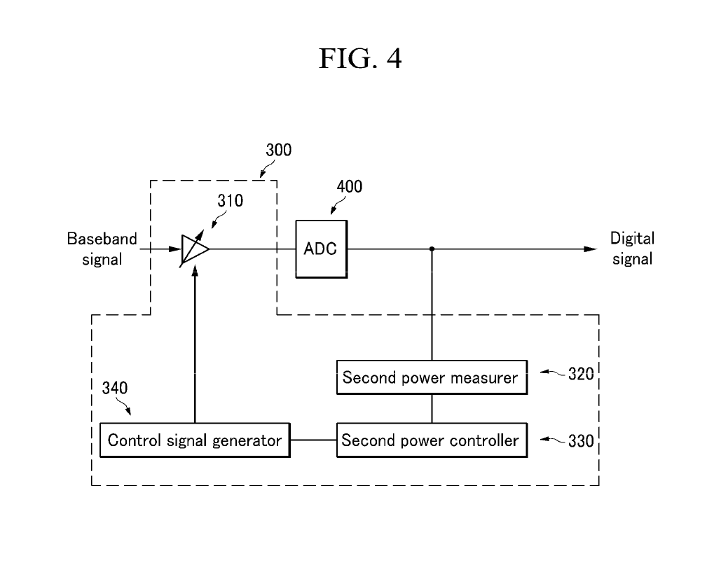

FIG. 4 shows a block diagram of the baseband signal processor of FIG. 1 according to the exemplary embodiment of the present invention. FIG. 4 illustrates only a part of the baseband signal process for description of the exemplary embodiment of the present invention.

As shown in FIG. 4, the baseband signal processor 300 includes an automatic gain control (AGC) amplifier 310, a second power measurer 320, a second power controller 330, and a control signal generator 340.

The AGC amplifier 310 generates a second amplified signal by amplifying the baseband signal with a second gain (S260). Herein, since the baseband signal has already been RF-amplified by a gain control of the low noise amplifier, a gain range of the AGC amplifier 310 for amplifying the baseband signal can be reduced. The AGC amplifier 310 changes a gain range by a control signal according to the second gain, and amplifies the baseband signal with a changed gain range. The second gain is determined by the strength measured by the second power measurer 320, and determination of the second gain will be described later in further detail.

The second power measurer 320 measures the strength of the second amplified signal with an update interval T (S270). In this instance, the second power measurer 320 measures the strength of the second amplified signal in the state of a digital signal. That is, as shown in FIG. 1, the ADC 400 receives the second amplified signal as an output signal of the AGC amplifier 310, and converts the second amplified signal in the state of an analog signal to the digital signal state and outputs the converted signal. In addition, the second power measurer 320 measures the strength of the second amplified signal in the digital signal state, which is an output signal of the ADC 400.

The update interval T denotes an interval for the second power measurer 320 to measure the strength of the second amplified signal, and is determined by the second power controller 330. Determination of the update interval T and determination of the second gain will now be described in further detail.

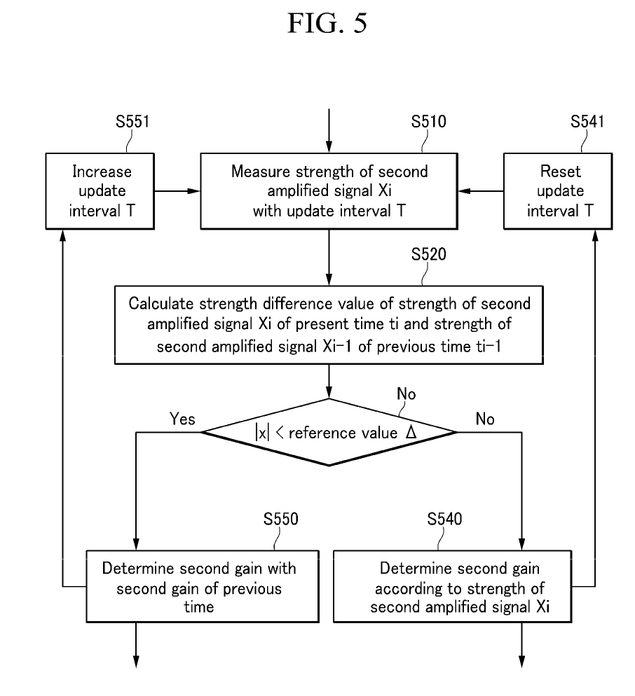

The second power controller 330 determines the second gain according to the strength of the second amplified signal (S280). The determination of the second gain will be described with reference to FIG. 5.

The second power controller 330 generates a control signal of the AGC amplifier 310 according to the second gain. The control gain generated by the second power controller 330 is a signal for digital voltage control such as pulse density modulation (PDM) and pulse width modulation (PWM). The PDM is a method of pulse modulation in which the duration of a pulse train is used to transfer the binary signal information (i.e., either 0 or 1).

The control signal generator 400 receives the digital voltage control signal as an output signal of the second power controller 300, converts the digital voltage control signal into an analog voltage control signal, and applies the analog voltage control signal to the AGC amplifier 310. The analog voltage control signal changes a gain range of the AGC amplifier 310.

Hereinafter, a method for the second power controller 330 to determine the second gain and the update interval T will be described in further detail with reference to FIG. 5.

FIG. 5 shows a flowchart of a secondary gain calculation method according to the exemplary embodiment of the present invention.

As shown in FIG. 5, the second power measurer 320 measures the strength Xᵢ of the second amplified signal according to the update interval T (S510). Herein, Xᵢ denotes an index of the second amplified signal strength measured by the second power measurer 320 at time tᵢ. Herein, tᵢ denotes an absolute time index. The update interval T is determined by the absolute time index tᵢ and an update coefficient N, and an initial value of the update interval T and an initial value of the update coefficient N can be determined in accordance with performance of the radio signal receiving apparatus or a characteristic of a radio signal to be received.

The second power controller 330 calculates a strength difference value |x| that corresponds to a difference between the strength Xᵢ of the second amplified signal at the present time tᵢ and the strength Xᵢ₋₁ of the second amplified signal at the previous time tᵢ₋₁ (S520). In addition, the second power controller 330 compares the strength difference value |x| with a reference value Δ of a predetermined strength difference value (S530). Herein, the reference value Δ can be determined by a strength difference value that implies no variation in the strength of the second amplified signal, and the determination of the reference value will not be further described since it can be easily realized by those skilled in the art.

When the strength difference value |x| is greater than the reference value Δ, the second power controller 330 determines a new second gain that is different from a second gain of the previous time tᵢ₋₁ according to the strength difference value |x| or the strength Xᵢ of the second amplified signal of the present time (S540). Since the change of the strength of radio signal due to a channel is too large to cause the new second gain to be generated, the second power controller 330 resets the update interval T and the update coefficient N with their initial values (S541).

When the strength difference value |x| is smaller than the reference value Δ, the second power controller 330 determines the second gain of the present time tᵢ to be a second gain of the next time tᵢ₊₁ (S550). Since the change of the strength of the second amplified signal is not too large to cause the second gain to be changed, the second power controller 330 sets an update interval after the present time tᵢ to be longer than the update interval of the present time.

That is, the second power controller 330 counts (N<−N+1) the update coefficient N and counts (tᵢ<−tᵢ₊₁) the absolute time index tᵢ when the strength difference value |x| is smaller than the reference value Δ, and increases the update interval T as shown in Equation 1 (S551).

T=tᵢ+(dt*N) [Equation 1]

In Equation 1, dt denotes a minimum time unit such as 1 us or 2 ms, and it can be changed in accordance with performance of the radio signal receiving apparatus.

In other words, it is assumed that a radio channel environment is slowly changed when a strength change rate of a received radio signal is small. Therefore, according to the exemplary embodiment of the present invention, comparison operation and control signal generation can be reduced by setting a time interval for measuring the strength of a radio signal for generating a control signal of the AGC amplifier to be longer than the present time interval when the strength difference value of the second amplified signal is smaller than the reference value. Accordingly, unnecessary noise and power consumption of the radio signal receiving apparatus can be reduced.

The above-described embodiments can be realized through a program for realizing functions corresponding to the configuration of the embodiments or a recording medium for recording the program in addition to through the above-described device and/or method, which is easily realized by a person skilled in the art.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A radio signal amplifying method comprising:
generating a first amplified signal by amplifying a radio signal with a first gain;
determining the first gain by measuring the strength of the first amplified signal;
frequency down-converting the first amplified signal for generating the down-converted signal;
generating a second amplified signal by amplifying the down-converted signal with a second gain; and
determining the second gain by measuring the strength of the second amplified signal.

2. The radio signal amplifying method of claim 1, wherein the generating the first amplified signal comprises amplifying the radio signal through a plurality of amplifiers, and the determining the first gain comprises determining turn-on/turn-off of each of the respective amplifiers according to the first gain.

3. The radio signal amplifying method of claim 2, wherein the determining the first gain further comprises measuring the strength of the first amplified signal in the state of an analog signal.

4. The radio signal amplifying method of claim 1, wherein the determining the second gain comprises:
measuring a strength difference value between the strength of the second amplified signal and the strength of a second amplified signal at a previous time;
generating the second gain according to the strength difference value when the strength difference value is greater than a reference value; and
maintaining the second gain at a level of the second gain of the previous time when the strength difference value is smaller than the reference value.

5. The radio signal amplifying method of claim 4, wherein the generating the second gain further comprises setting a time interval for measuring the strength of the second amplified signal with an initial value.

6. The radio signal amplifying method of claim 4, wherein the maintaining the second gain at the level of the second gain of the previous time further comprises setting a time interval for measuring the strength of the second amplified signal to be longer than the present time interval.

7. The radio signal amplifying method of claim 4, wherein the determining the second gain further comprises measuring the strength of the second amplified signal in the state of a digital signal.

8. A radio signal receiving apparatus comprising:
an amplifying end for generating a first amplified signal by amplifying a radio signal with a first gain;
a first strength measurer for measuring the strength of the first amplified signal;
a first power controller for determining the first gain according to the strength of the first amplified signal;
a mixer for generating a down-converted signal by frequency down-converting the first amplified signal;
an amplifier for generating a second amplified signal by amplifying the down-converted signal with a second gain;
a second measurer for measuring the strength of the second amplified signal; and
a second power controller for determining the second gain according to the strength of the second amplified signal.

9. The radio signal receiving apparatus of claim 8, wherein the amplifying end comprises:
a plurality of amplifiers respectively amplifying an input signal with each gain and outputting an amplified signal; and
a plurality of switches respectively determining turn-on/turn-off of each of the plurality of amplifiers.

10. The radio signal receiving apparatus of claim 8, wherein the first power controller applies an on-off control signal to the plurality of switches that are respectively connected with the plurality of amplifiers according to the first gain.

11. The radio signal receiving apparatus of claim 8, wherein the first strength measurer measures the strength of the first amplified signal in the state of an analog signal.

12. The radio signal receiving apparatus of claim 8, further comprising a converter for converting the second amplified signal from an analog format to a digital format.

13. The radio signal receiving apparatus of claim 12, wherein the second strength measurer measures the second amplified signal in the state of a digital signal.

14. The radio signal receiving apparatus of claim 8, wherein the second power controller generates the second gain when a strength difference value between the second amplified signal and a second amplified signal of the previous time is greater than a reference value.

15. The radio signal receiving apparatus of claim 14, wherein the second power controller sets a time interval for the second strength measurer to measure the strength of the second amplified signal with an initial value when the strength difference value is greater than the reference value.

16. The radio signal receiving apparatus of claim 8, wherein the second power controller maintains the second gain at a level of a second gain of a previous time when a strength difference value between the second amplified signal and a second amplified signal of the previous time is smaller than a reference value.

17. The radio signal receiving apparatus of claim 16, wherein the second power controller sets a time interval for the second strength measurer to measure the strength of the second amplified signal to be longer than a time interval of the present time when the strength difference value is smaller than the reference value.

18. The radio signal receiving apparatus of claim 8, further comprising a control signal generator for generating a control signal that changes a gain resistance of the amplifier according to the second gain.
